(19) United States
(12) Patent Application Publication
(10) Pub. No.: US 2012/0132943 A1
(43) Pub. Date: May 31, 2012

(54) SEMICONDUCTOR LIGHT EMITTING DEVICE

(75) Inventors: Toshiki HIKOSAKA, Kanagawa-ken (JP); Hajime Nago, Kanagawa-ken (JP); Koichi Tachibana, Kanagawa-ken (JP); Toshihide Ito, Tokyo (JP); Shinya Nunoue, Chiba-ken (JP)

(73) Assignee: KABUSHIKI KAISHA TOSHIBA, Tokyo (JP)

(21) Appl. No.: 13/204,013

(22) Filed: Aug. 5, 2011

(30) Foreign Application Priority Data
Nov. 29, 2010 (JP) 2010-264603

(51) Int. Cl. H01L 33/58

(52) U.S. Cl. 257/98; 257/E33.074

(57) ABSTRACT

According to one embodiment, a semiconductor light emitting device includes an n-type semiconductor layer, an electrode, a p-type semiconductor layer and a light emitting layer. The p-type semiconductor layer is provided between the n-type semiconductor layer and the electrode and includes a p-side contact layer contacting the electrode. The light emitting layer is provided between the n-type and the p-type semiconductor layers. The p-side contact layer includes a flat part having a plane perpendicular to a first direction from the n-type semiconductor layer toward the p-type semiconductor layer and multiple protruding parts protruding from the flat part toward the electrode. A height of the multiple protruding parts along the first direction is smaller than one-fourth of a dominant wavelength of light emitted from the light emitting layer. A density of the multiple protruding parts in the plane is 5×10⁷/cm² or more and 2×10⁸/cm² or less.

### CROSS-REFERENCE TO RELATED APPLICATIONS

This application is based upon and claims the benefit of priority from the prior Japanese Patent Application No. 2010-264603, filed on Nov. 29, 2010; the entire contents of which are incorporated herein by reference.

### FIELD

Embodiments described herein relate generally to a semiconductor light emitting device.

### BACKGROUND

A nitride semiconductor is used in a semiconductor light emitting device. In such a semiconductor light emitting device, it is difficult to spread current injected from an electrode into a semiconductor layer, in a lateral direction. Therefore, the current is injected mainly into the semiconductor layer directly under the electrode. When the electrode has a light shielding property, the light emitted in a light emitting layer directly under the electrode is blocked by the electrode.

It is possible to cause the emitted light to transmit a positive polarity electrode (p-type electrode) to be extracted by using a transparent electrode as the positive polarity electrode (p-type electrode). A conductive material such as ITO (In₂O₃—SnO₂) is used as the transparent electrode. When the transmittance of the transparent electrode is made high for improving light extraction efficiency, the contact resistance between the semiconductor layer and the transparent electrode becomes high to increase drive voltage.

Meanwhile, there is a configuration in which a semiconductor layer is provided with a protrusion of, for example, approximately 1.5 μm and an optimum angle is substantially increased to improve the light extraction efficiency.

### BRIEF DESCRIPTION OF THE DRAWINGS

FIG. 1 is a schematic cross-sectional view showing a semiconductor light emitting device according to an embodiment;

FIGS. 2A and 2B are schematic cross-sectional views showing a part of the semiconductor light emitting devices according to the embodiment;

FIG. 3 is a schematic cross-sectional view showing a part of the semiconductor light emitting device according to the embodiment;

FIGS. 4A and 4B are schematic views showing characteristics of the semiconductor light emitting device according to the embodiment;

FIGS. 5A and 5B are schematic views showing characteristics of a semiconductor light emitting device of a reference example;

FIGS. 6A and 6B are graphs showing characteristics of the semiconductor light emitting device;

FIG. 7 is a graph showing characteristics of the semiconductor light emitting device;

FIGS. 8A and 8B are schematic views showing characteristics of the semiconductor light emitting device according to the embodiment; and

FIGS. 9A to 9D are schematic views showing characteristics of the semiconductor light emitting device according to the embodiment.

### DETAILED DESCRIPTION

In general, according to one embodiment, a semiconductor light emitting device includes an n-type semiconductor layer, an electrode, a p-type semiconductor layer and a light emitting layer. The p-type semiconductor layer is provided between the n-type semiconductor layer and the electrode and includes a p-side contact layer contacting the electrode. The light emitting layer is provided between the n-type semiconductor layer and the p-type semiconductor layer. The p-side contact layer includes a flat part having a plane perpendicular to a first direction from the n-type semiconductor layer toward the p-type semiconductor layer and multiple protruding parts protruding from the flat part toward the electrode. A height of the multiple protruding parts along the first direction is smaller than one-fourth of a dominant wavelength of light emitted from the light emitting layer. A density of the multiple protruding parts in the plane is 5×10⁷/cm² or more and 2×10⁸/cm² or less.

In general, according to one embodiment, a semiconductor light emitting device includes an n-type semiconductor layer, an electrode, a p-type semiconductor layer and a light emitting layer. The p-type semiconductor layer is provided between the n-type semiconductor layer and the electrode and includes a p-side contact layer contacting the electrode. The light emitting layer is provided between the n-type semiconductor later and the p-type semiconductor layer. The p-side contact layer includes a first region provided in a plane perpendicular to a first direction from the n-type semiconductor layer toward the p-type semiconductor layer and multiple second regions distributed within the first region in the plane. A concentration of p-type impurity contained in the second region is higher than a concentration of p-type impurity contained in the first region. A density of the multiple second regions in the plane is 5×10⁷/cm² or more and 2×10⁸/cm² or less.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### EMBODIMENT

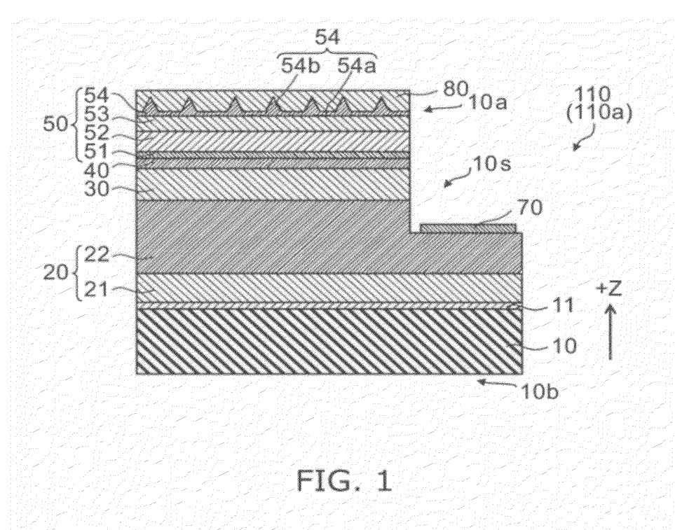

FIG. 1 is a schematic cross-sectional view illustrating the configuration of a semiconductor light emitting device according to an embodiment.

As shown in FIG. 1, the semiconductor light emitting device 110 according to the embodiment is provided with an n-type semiconductor layer 20, an electrode (p-side electrode 80), a p-type semiconductor layer 50, and a light emitting layer 40.

Furthermore, the semiconductor light emitting device 110 is provided with an n-side electrode 70. In the specific example, the semiconductor light emitting device 110 is provided with a multilayer stacked body 30, a substrate 10, and a buffer layer 11. The multilayer stacked body 30, the substrate 10, and the buffer layer 11 may be provided as needed and may be omitted.

A nitride semiconductor is used as the n-type semiconductor layer 20, the p-type semiconductor layer 50, and the light emitting layer 40, for example.

The p-type semiconductor layer 50 is provided between the n-type semiconductor layer 20 and the p-side electrode 80. The p-type semiconductor layer 50 includes a p-side contact layer 54 which contacts the p-side electrode 80. That is, the p-type semiconductor layer 50 contacts the p-side electrode 80.

In the specific example, the p-type semiconductor layer 50 further includes a first p-type layer 51, a second p-type layer 52, and a third p-type layer 53. The first p-type layer 51 is provided between the p-side contact layer 54 and the light emitting layer 40. The second p-type layer 52 is provided between the p-side contact layer 54 and the first p-type layer 51. The third p-type layer 53 is provided between the p-side contact layer 54 and the second p-type layer 52.

A p-type AlGaN layer is used as the first p-type layer 51, for example. The first p-type layer 51 can function as an electron-overflow suppression layer (electron-overflow prevention layer), for example.

A p-type GaN layer is used as the second p-type layer 52, for example.

A p-type GaN layer is used as the third p-type layer 53, for example. The concentration of p-type impurity included in the third p-type layer 53 is higher than the concentration of the p-type impurity included in the second p-type layer 52, for example. The third p-type layer 53 can function as a contact layer.

A p-type GaN layer is used as the p-side contact layer 54, for example. The p-type impurity concentration in the p-side contact layer 54 is higher than the p-type impurity concentration included the third p-type layer 53. In this manner, in the semiconductor light emitting device 110, a configuration using the two layers of the third p-type layer 53 and the p-side contact layer 54 is employed for a contact layer.

The embodiment is not limited to this example, and the third p-type layer 53 may be omitted. That is, in the embodiment, the first p-type layer 51, the second p-type layer 52 and the third p-type layer 53 may be provided as needed and configured optionally.

Mg (magnesium) is used as the p-type impurity, for example.

The n-type semiconductor layer 20 includes an underlayer 21 and an n-side contact layer 22. The n-side contact layer 22 is provided between the underlayer 21 and the light emitting layer 40. A GaN layer is used as the underlayer 21, for example. A GaN layer including n-type impurity is used as the n-side contact later 22.

Si (silicon) is used as the n-type impurity, for example.

In this manner, the specific example is provided with a stacked structure body 10s including the n-type semiconductor layer 20, the light emitting layer 40, and the p-type semiconductor layer 50. The direction from the n-type semiconductor layer 20 toward the p-type semiconductor layer is defined as a Z-axis direction (first direction or stacking direction). The stacked structure body 10s has a first major surface 10a on the side of the p-type semiconductor layer 50 and a second major surface 10b on the n-type semiconductor layer 20. Here, one direction perpendicular to the Z-axis direction is defined as an X-axis direction. The direction perpendicular to the Z-axis direction and perpendicular to the X-axis direction is defined as a Y-axis direction.

In the specific example, the stacked structure body 10s is selectively removed at a part on the side of the first major surface 10a. Therefore, a part of the n-type semiconductor layer 20 is exposed on the side of the first major surface 10a. An n-side electrode 70 is provided on this exposed part. The n-side electrode 70 contacts the n-type semiconductor layer 20. The embodiment is not limited to this example, the n-side electrode 70 may be provided on the n-type semiconductor layer 20 on the side of the second major surface 10b.

A composite film of titan-platinum-gold (Ti/Pt/Au) may be used as the n-side electrode 70, for example. The thickness of the Ti film is approximately 0.05 micrometer (μm), the thickness of the Pt film is approximately 0.05 μm, and the thickness of the Au film is approximately 1.0 μm, for example.

The p-side electrode 80 contacts the p-type semiconductor layer 50. Specifically, the p-side electrode 80 contacts the p-side contact layer 54. Indium tin oxide (ITO) or the like is used as the p-side electrode 80, for example. When the ITO is used as the p-side electrode 80, the thickness of the p-side electrode 80 is 0.25 μm, for example. The embodiment is not limited to this example, and a composite film such as nickel-gold (Ni/Au) can be used as the p-side electrode 80. Furthermore, a metal layer can be provided on the p-side electrode 80 as a pad electrode.

The multilayer stacked body 30 includes multiple first layers (not shown in the drawing) and multiple second layers (not shown in the drawing) which are stacked alternately. The first layer is a GaN layer, for example. The thickness of the first layer is 3 nanometer (nm), for example. The second layer is an InGaN layer, for example. The thickness of the second layer is 1 nm, for example. The number of the first layers is 21, for example. The number of the second layers is 20, for example. The multilayer stacked body 30 is a super-lattice layer, for example.

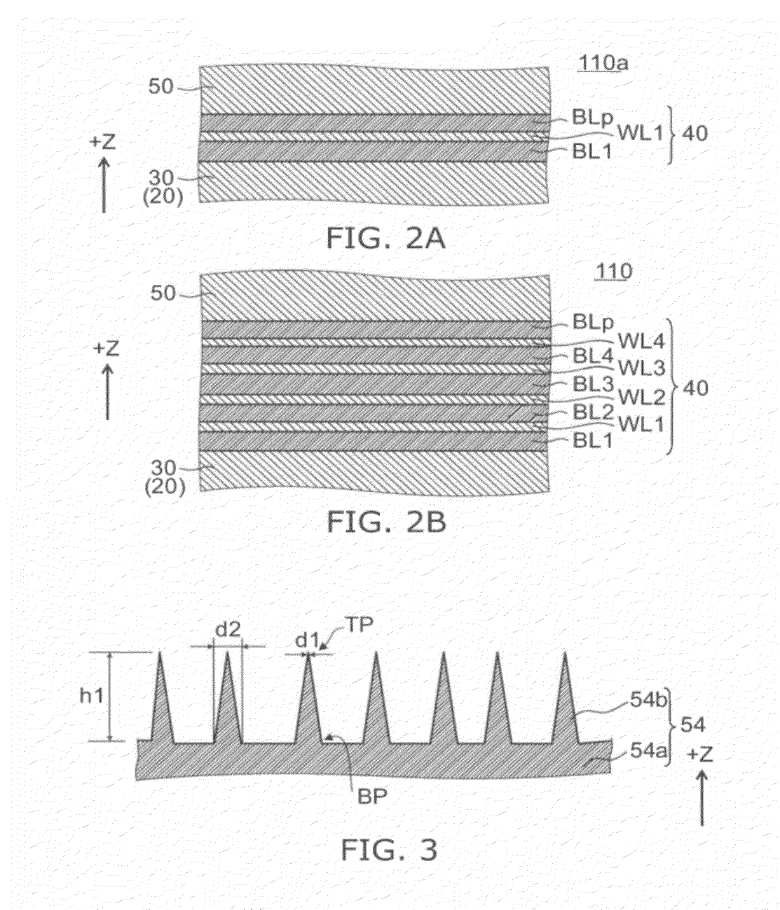

FIGS. 2A and 2B are schematic cross-sectional views illustrating partial configurations of the semiconductor light emitting devices according to the embodiment.

That is, these drawings show configuration examples of the light emitting layer 40.

As shown in FIG. 2A, in a semiconductor light emitting device 110a according to the embodiment, the light emitting layer 40 includes multiple barrier layers (first barrier layer BL1 and p-side barrier layer BLp) and a well layer (first well layer WL1) provided between the multiple barrier layers. In this example, the number of the well layers is one. That is, the light emitting layer 40 can have a single quantum well (SQW) structure.

As shown in FIG. 2B, in the semiconductor light emitting device 110, the light emitting layer 40 includes multiple barrier layers (first barrier layer BL1 to nth barrier layer BLn and a p-side barrier layer BLp) and multiple well layers (first well layer WL1 to nth well layer WLn) each provided between the multiple barrier layers. Here, “n” is an integer equal to or larger than two. In this example, the number of the well layers is plural. That is, the light emitting layer 40 can have a multiple quantum well (MQW) structure. “n” is eight, for example.

An un-doped GaN layer is used as the barrier layer. The thickness of the barrier layer is set to approximately 10 nm, for example. An un-doped In_{0.15}G_{0.85}N layer is used as the well layer, for example. The thickness of the well layer is set to 2.5 nm, for example.

It should be noted that the light emitting layer 40 may be configured optionally in the embodiment.

A nitride semiconductor is used as the barrier layer and the well layer. A nitride semiconductor including indium (In) is used as the well layer. Band gap energy of the barrier layer is larger than the band gap energy of the well layer. For example, when the barrier layer includes In, for example, In concentration in the barrier layer is lower than the In concentration in the well layer.

It should be noted that the barrier layer and the well layer are designed so as to cause the light emitted from the light emitting layer 40 to have a desired wavelength. A dominant wavelength of the light emitted from the light emitting layer 40 is 380 nm or more and 650 nm or less, for example. Here, the dominant wavelength is a wavelength providing the highest intensity in the spectrum of the light emitted from the light emitting layer 40. For example, the photoluminescence wavelength of the light emitting layer 40 is 450 nm at the room temperature.

Hereinafter, explanation will be provided about the semiconductor light emitting device 110 in which the light emitting layer 40 has the MQW structure. Sapphire is used as the substrate 10, for example. The buffer layer 11 is formed on the substrate 10. A GaN layer is used as the buffer layer 11, for example. On the buffer layer 11, the n-type semiconductor layer 20, the multilayer stacked body 30, the light emitting layer 40, and the p-type semiconductor layer 50 are formed sequentially. The substrate 10 may be removed after the above semiconductor layers have been formed on the buffer layer 11.

As shown in FIG. 1, in the semiconductor light emitting device 110 according the embodiment, the p-side contact layer 54 has a flat part 54a and multiple protruding parts 54b. The multiple protruding parts 54b are provided between the flat part 54a and the p-side electrode 80. The multiple protruding parts 54b protrude from the flat part 54a toward the p-side electrode 80. The respective side surfaces and upper parts of the multiple protruding parts 54b are surrounded by the p-side electrode 80.

FIG. 3 is a schematic cross-sectional view illustrating a partial configuration of the semiconductor light emitting device according to the embodiment. That is, the drawing shows a configuration example of the p-side contact layer 54.

As shown in FIG. 3, the flat part 54a has a plane perpendicular to the Z-axis direction (e.g., plane parallel to the X-Y plane, for example). That is, the flat part 54a is a layer extending in a plane perpendicular to the Z-axis direction. The protruding part 54b protrudes from the flat part 54a toward the p-side electrode 80.

The height h1 of the multiple protruding parts 54b along the Z-axis direction is smaller than one-fourth of the wavelength of the light emitted from the light emitting layer 40.

Then, the density of the multiple protruding parts 54b in a plane perpendicular to the Z-axis direction is 5×10⁷/cm² or more and 2×10⁸/cm² or less.

Therefore, the drive voltage of the semiconductor light emitting device can be reduced.

By the above configuration, the contact resistance between the p-side contact layer 54 and the p-side electrode 80 can be reduced.

It should be noted that the density of the protruding parts 54b can be obtained by way of photographing the surface of the p-side contact layer 54 using an atomic force microscope and providing the photographed result with data processing.

The protruding part 45b has a pyramid shape. The protruding part 54b has a polygonal pyramid shape, for example. That is, each of the multiple protruding parts 54b has a base side part BP and a tip part TP. The base side part BP is disposed on a side of the flat part 54a of the multiple protruding parts 54b. The tip part TP is disposed on an end side of the multiple protruding parts 54b. The head size of the protruding part 54b is smaller than the base part size of the protruding part 54b. That is, the diameter d1 of a tip part TP cut by a plane perpendicular to the Z-axis direction in each of the multiple protruding parts is smaller than the diameter d2 of the base side part BP cut by the plane in the each of the multiple protruding parts 54b.

The diameter d2 in each of the multiple protruding parts 54b at a part on the side of the flat part 54a is equal to or smaller than 400 nm, for example.

The height h1 is equal to or smaller than 50 nm, for example. More specifically, the height h1 is equal to or smaller than 20 nm.

In the case of the diameter d2 larger than 400 nm, when Mg is doped at a high concentration, substantially the same state occurs as the uniform formation of a part having a high Mg concentration. A crystalline defect is easily caused and the contact resistance R is easily increased in this state.

In the case of the height h1 larger than 50 nm, when Mg is doped at a high concentration, the crystalline defect is easily caused and the contact resistance R is easily increased.

It has been found in an independent experiment carried out by the inventors that the contact resistance can be reduced and the drive voltage can be reduced by way of providing such protruding parts 54b. In the following, this experiment will be explained. That is, a fabricated sample and an evaluation result thereof will be explained.

First, the substrate 10 (sapphire substrate) was subjected to the processing of organic cleaning and acid cleaning. After that, the substrate 10 was introduced into a reaction chamber of an MOCVD system and a GaN layer was formed as the buffer layer 11 by the use of tri-methyl gallium (TMG) and ammonia (NH₃). The thickness of the buffer layer 11 is 20 nm.

Next, an un-doped GaN layer was formed as the underlayer 21 at 1120° C. by the use of nitrogen and hydrogen as carrier gas and by the use of TMG and NH₃. The thickness of the underlayer 21 is 2 μm.

Subsequently, an n-type GaN layer was formed as the n-side contact layer 22 at 1120° C. by the use of nitrogen and hydrogen as carrier gas and by the use of TMG, NH₃, and silane (SiH₄). The thickness of the n-side contact layer 22 is 4 μm. The SiH₄ is a source material of the n-type impurity.

Next, an un-doped GaN layer was formed at 800° C. in a nitrogen atmosphere by the use of TMG and NH₃, and subsequently tri-methyl indium (TMI) was further added at 800° C. and an un-doped In_{0.07}Ga_{0.93}N layer was formed. The un-doped GaN layer becomes the first layer. The thickness of the first layer is 3 nm. The un-doped In_{0.07}Ga_{0.93}N layer becomes the second layer. The thickness of the second layer is 1 nm. After that, the above forming of the first layer and the second layer was repeated. The forming of the first layer and the second layer was carried out 20 times in total. Then, finally, the first layer was formed additionally. Therefore, the multilayer stacked body 30 is formed.

Next, an un-doped GaN layer was formed as the barrier layer in a nitrogen atmosphere by the use of TMG and NH₃. The thickness of the barrier layer is 5 nm. Subsequently, an un-doped In_{0.15}Ga_{0.85}N layer was formed as the well layer by the use of TMG, TMI, and NH₃. The thickness of the well layer is 2.5 nm. The above forming of the barrier layer and the well layer was repeated. The forming of the barrier layer and the well layer was carried out eight times in total. Furthermore, finally, the barrier layer was formed. Therefore, the light emitting layer 40 is formed.

Next, a p-type AlGaN layer was formed as the first p-type layer 51 at 1000° C. in an atmosphere including nitrogen and hydrogen by the use of TMA, TMG, NH₃, and Bis(cyclopentadienyl)magnesium (Cp₂Mg). The CP₂Mg is a source material of the p-type impurity. The thickness of the first p-type layer 51 is 10 nm.

Furthermore, a p-type GaN layer was formed as the second p-type layer 52 in an atmosphere including nitrogen and hydrogen by the use of TMG, NH₃, and CP₂Mg. The thickness of the second p-type layer 52 is 80 nm.

Next, a p-type GaN layer was formed as the third p-type layer 53 in an atmosphere including nitrogen and hydrogen by the use of TMG, NH₃, and CP₂Mg. The thickness of the third p-type layer 53 is 5 nm.

Furthermore, the supply ratio of the nitrogen, hydrogen, and ammonia was changed and also the supply amount of the CP₂Mg was increased, and a p-type GaN layer was formed as the p-side contact layer 54. The thickness of the p-side contact layer 54 is 5 nm in average.

The p-side contact layer 54 has the flat part 54a and the protruding part 54b. The thickness of the flat part 54a is 4 nm, for example, and the height of the protruding parts 54b is approximately 5 nm. Considering the density of the protruding parts 54b, the thickness of the p-side contact layer 54 becomes approximately 5 nm when the thicknesses of the flat part 54a and the protruding part 54b are totaled and averaged.

After the above crystal growth, the temperature was reduced to the room temperature.

A part of the stacked structure body 10s obtained in the above manner was removed until a part of the n-side contact layer 22 was reached. A Ti/Pt/Au stacked film was formed on the thereby exposed n-side contact layer 22 as the n-side electrode 70. Furthermore, an ITO film was formed on the p-side contact layer 54 as the p-side electrode 80.

Therefore, the semiconductor light emitting device is obtained.

In the experiment, the semiconductor light emitting device was formed in the several forming conditions of the p-type GaN layer as the p-side contact layer 54. Then, the surface state of the p-side contact layer 54 was evaluated.

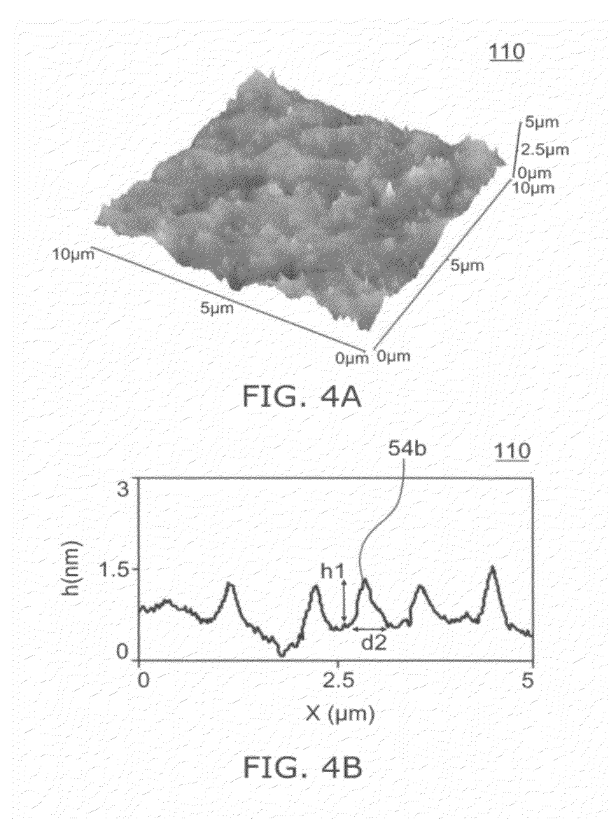

FIGS. 4A and 4B are schematic views illustrating characteristics of the semiconductor light emitting device according to the embodiment.

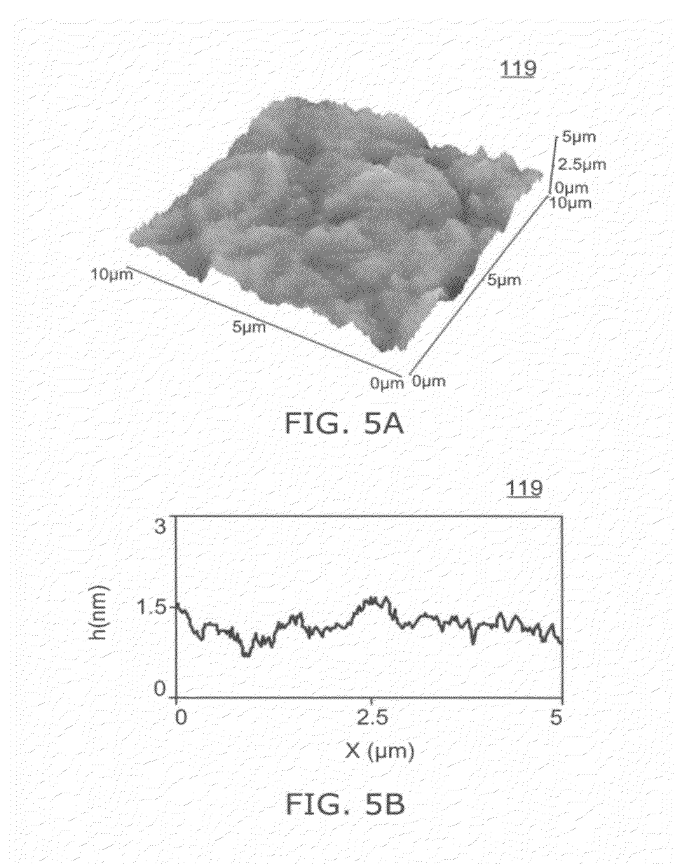

FIGS. 5A and 5B are schematic views illustrating characteristics of a semiconductor light emitting device of a reference example.

That is, each of FIG. 4A and FIG. 5A is an atomic force microscope (AFM) image of the p-type GaN layer as the p-side contact layer 54. Each of these images shows a region of a 10 μm square. The height scale is 5 nm.

FIG. 4B and FIG. 5B shows cross-sectional profiles of the p-side contact layers 54 obtained from FIG. 4A and FIG. 5A, respectively. The horizontal axis of each of FIG. 4B and FIG. 5B is a position in the X-axis direction. The vertical axis is a surface height along the Z-axis direction. FIG. 4A and FIG. 4B corresponds to the semiconductor light emitting device 110 according to the embodiment, and FIG. 5A and FIG. 5B correspond to the semiconductor light emitting device 119 of the reference example.

Between the semiconductor light emitting device 110 and the semiconductor light emitting device 119, the forming condition of the p-type GaN layer as the p-side contact layer 54 is different. Specifically, in the formation of the p-type GaN layer as the p-side contact layer 54, the supply amount of the p-type impurity for the semiconductor light emitting device 110 is larger than the supply amount of the p-type impurity for the semiconductor light emitting device 119.

As shown in FIG. 4A, in the semiconductor light emitting device 110, the protruding part 54b is formed in the p-side contact layer 54. The protruding part 54b has a polygonal pyramid shape.

As shown in FIG. 4B, the height h1 of the protruding part 54b is approximately 0.5 nm to 1 nm. The diameter d2 in each of the multiple protruding parts 54b at a part on the side of the flat part 54a is approximately 400 nm. The root-mean-square surface roughness (RMS) of this surface is 0.34 nm.

In the semiconductor light emitting device 110 having such protruding parts 54b, the contact resistance was 1.7×10⁻³ Ωcm².

Meanwhile, as shown in FIGS. 5A and 5B, the p-side contact layer 54 is observed not to have a clearly defined protruding part in the semiconductor light emitting device 119 of the reference example. The RMS of this surface was 0.24 nm. That is, protruding parts are not formed in the p-side contact layer 54.

It should be noted that the contact resistance was 5.0×10⁻² Ωcm² in the semiconductor light emitting device 119.

In this manner, the semiconductor light emitting device 110 and the semiconductor light emitting device 119 are different from each other for the protruding parts 54b and also for the contact resistance.

In the embodiment, the root-mean-square surface roughness (RMS) on the surface of the p-side contact layer 54 is larger than 0.3 nm.

In this manner, it has been found that there are cases in which the protrusions 54b are formed and not formed in the p-side contact layer 54 depending on the forming condition of the p-type GaN layer as the p-side contact layer 54. Samples were fabricated in the several forming condition s of the p-type GaN layer as the p-side contact layer 54, and the change in the density of the protruding parts 54b was evaluated. Furthermore, the contact resistance and the drive voltage at this time were evaluated.

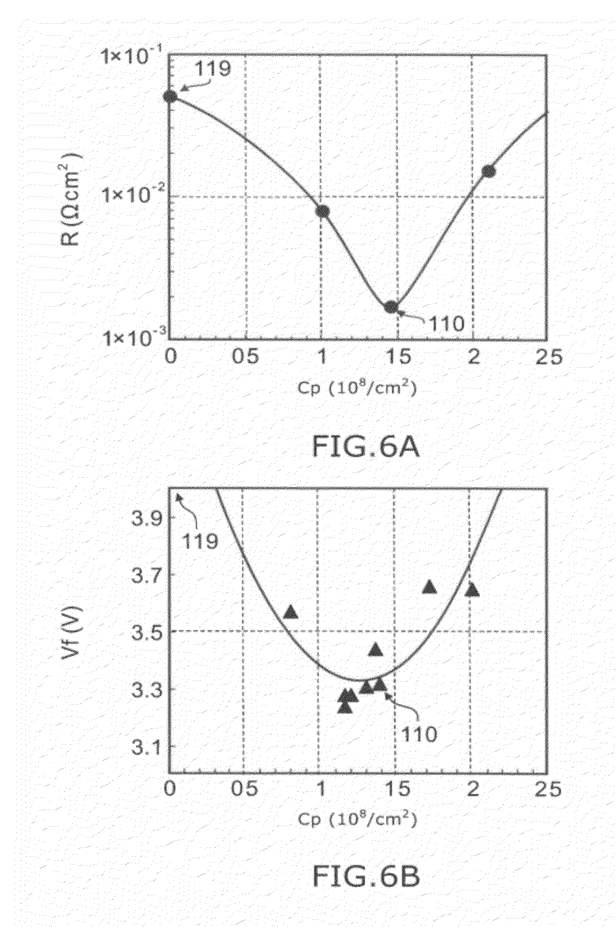

FIGS. 6A and 6B are graphs illustrating characteristics of the semiconductor light emitting device.

That is, FIG. 6A shows the contact resistance and FIG. 6B shows the drive voltage. The horizontal axis in each of these drawings is the density Cp of the protruding parts 54b (density of the protruding parts 54b in the plane perpendicular to the Z-axis direction). The vertical axis of FIG. 6B is the contact resistance R between the p-side contact layer 54 and the p-side electrode 80. The vertical axis of FIG. 6B is the drive voltage Vf of the semiconductor light emitting device. The drive voltage Vf is a voltage at a current of 20 milliampere (mA).

As shown in FIG. 6A, when the density Cp of the protruding parts 54b is zero, that is when the protruding parts 54b are not formed, the contact resistance R is large as 5×10⁻² Ωcm². This condition corresponds to the semiconductor light emitting device 119 of the reference example. As the density Cp of the protruding parts 54b becomes higher, the contact resistance R is reduced. However, when the density Cp exceeds 1.5×10⁸/cm² the contact resistance R is increased. In this manner, when the density Cp has a value in a specific range, the contact resistance R is reduced.

The reason why the contact resistance R is reduced as the density Cp becomes higher would be that the contact area between the p-side contact layer 54 and the p-side electrode 80 is increased as the density Cp becomes higher. When the density Cp becomes too high, Mg segregation is caused, for example, and the crystalline quality of the p-side contact layer 54 is easily degraded. Therefore, when the density Cp becomes too high, the contact resistance R would be increased.

From FIG. 6A, it is found that the contact resistance R is reduced when the density Cp of the protruding parts 54b is 5×10⁷/cm² or more and 2×10⁸/cm² or less. That is, the reduction effect of the contact resistance R is obtained practically in this range.

As shown in FIG. 6B, the drive voltage Vf is reduced when the density of the protruding parts 54b is in a specified range. In particular, when the density Cp of the protruding parts 54b is 5×10⁷/cm² or more and 2×10⁸/cm² or less, the drive voltage Vf is low.

The density of the protruding parts 54b can be obtained by way of measuring the number of the protruding parts 54b in a certain area (e.g., 10 μm square) from the AFM image, for example.

In the semiconductor light emitting device 110 according to the embodiment, the contact resistance R is reduced by way of setting the density Cp of the protruding parts 54b in the above range. Therefore, a heat generation amount is increased little even when the current is increased. Accordingly, it is possible to suppress the degradation of the light emission characteristic and reliability which are caused by the heat generation. That is, it is possible to improve the light emission characteristic and to improve the reliability in the semiconductor light emitting device to which a large current is applied for a high output power.

The density Cp of the protruding parts 54b is found to be changed depending on the forming condition of the p-side contact layer 54. For example, the density Cp of the protruding parts 54b is changed by the concentration (average concentration) of Mg elements introduced into the p-side contact layer 54 in the formation of the p-side contact layer 54.

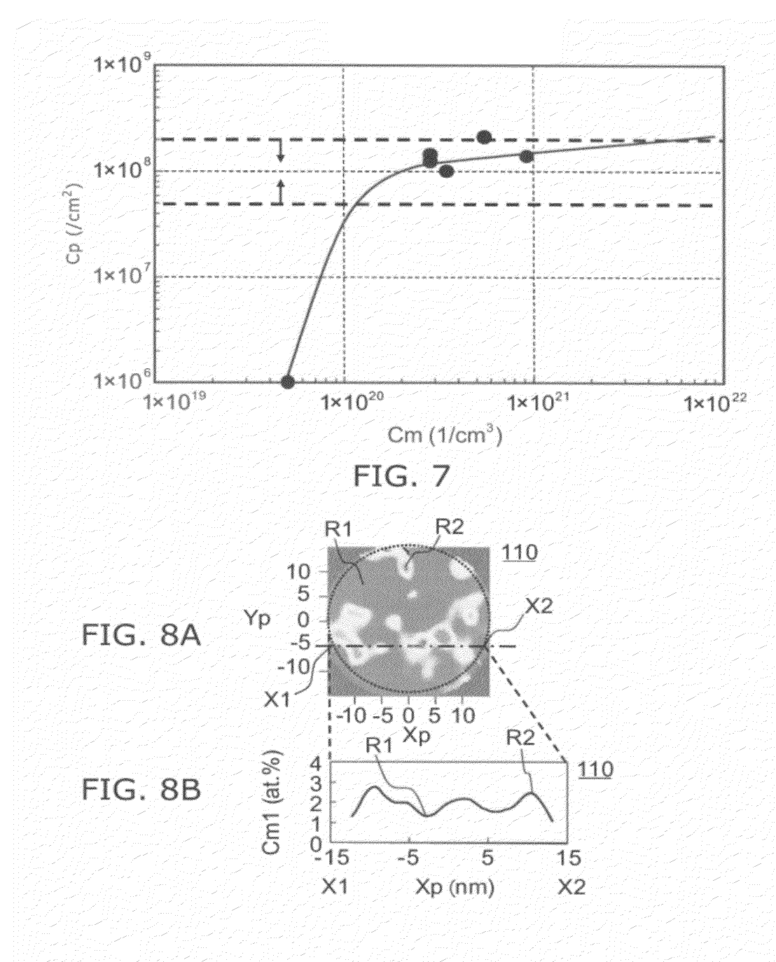

FIG. 7 is a graph illustrating characteristics of the semiconductor light emitting device.

That is, the drawing shows a relationship between the Mg concentration Cm in the p-side contact layer 54 and the density Cp of the protruding parts 54b. The Mg concentration Cm shows a result obtained by analysis of the p-side contact layer 54 by a secondary ion mass spectroscopy (SIMS) measurement. In this analysis, the analyzed area is approximately 200×200 μm². In this analysis, average Mg densities can be obtained both in the depth direction and the layer surface direction of the p-side contact layer 54, respectively.

As shown in FIG. 7, when the Mg concentration Cm becomes higher in the p-side contact layer 54, the density Cp of the protruding parts 54b is increased.

For example, when the Mg concentration Cm is 5×10¹⁹/cm³, the density Cp of the protruding parts 54b is 1×10⁶/cm². For example, when the Mg concentration Cm is 3×10²⁰/cm³, the density Cp of the protruding parts 54b is drastically increased to 1.5×10⁸/cm². Then, when the Mg concentration Cm is in a range higher than 3×10²⁰/cm³, the density Cp of the protruding parts 54b increases gradually.

It should be noted that, in a range of the Mg concentration Cm from 3×10²⁰/cm³ to 1×10²¹/cm³, when the Mg concentration Cm became higher, it was found that the size (diameter d2) of the protruding part 54b tended to be increased.

When the Mg concentration Cm is 1×10²⁰/cm³ or more and 1×10²¹/cm³ or less, the density Cp of the protruding parts 54b is 5×10⁷/cm² or more and 2×10⁸/cm² or less.

From the experimental result illustrated in FIG. 7, it is found that, when the Mg concentration Cm is 1×10²⁰/cm³ or more and 5×10²¹/cm³ or less, the density Cp of the protruding parts 54b can be made 5×10⁷/cm² or more and 2×10⁸/cm² or less.

Accordingly, in the embodiment, the concentration (e.g., average concentration) of Mg included in the p-side contact layer 54 is preferably set to 1×10²⁰/cm³ or more and 5×10²¹/cm³ or less.

Furthermore, specifically, the Mg concentration (e.g., average concentration) is preferably set to 1×10²⁰/cm³ or more and 1×10²¹/cm³ or less.

When the concentration of Mg included in the p-side contact layer 54 is lower than 1×10²⁰/cm³, activation of the Mg becomes insufficient in the p-side contact layer 54. Therefore, the contact resistance R between the p-side contact layer 54 and the p-side electrode 80 is increased. Furthermore, the concentration of Mg included in the p-side contact layer 54 is higher than 5×10²¹/cm³, the crystalline quality in the p-side contact layer 54 is degraded and the contact resistance R is also increased.

Generally, when Mg is doped at a concentration of 1×10²⁰/cm³ or more, a crystalline defect and polarity reversal are caused and the crystalline quality is degraded. However, when the protruding parts 54b are provided in the p-side contact layer 54, degradation is not easily caused by the defect and the polarity reversal even when Mg is doped at a high concentration. Therefore, Mg can be doped at a high concentration. Accordingly, it becomes possible to form the p-side contact layer 54 having a high crystalline quality and a high concentration.

FIGS. 8A and 8B are schematic views illustrating characteristics of the semiconductor light emitting device according to the embodiment.

That is, FIG. 8A is a chart schematically showing an exemplary result of evaluation for a Mg element distribution in the p-side contact layer 54 of the semiconductor light emitting device 110 using a three-dimensional atom probe measurement. The horizontal direction of this chart is the X-axis direction (position Xp in the X-axis direction) and the vertical direction is the Y-axis direction (position Yp in the Y-axis direction). In this chart, a higher intensity part of the image corresponds to a part having a higher concentration of Mg elements and a lower intensity part of the image corresponds to a part having a lower concentration of Mg elements.

FIG. 8B shows a distribution in the concentration Cm1 of Mg included in the p-side contact layer 54 of the semiconductor light emitting device 110 along the X-axis direction. The horizontal axis of FIG. 8B is a position in the X-axis direction. The positions X1 and X2 shown in FIG. 8B correspond to the positions X1 and X2 shown in FIG. 8A, respectively. The vertical axis of FIG. 8B is the Mg concentration Cm1. The concentration Cm1 is expressed by an atomic percentage.

As shown in FIG. 8A, a region having a high Mg concentration is formed in the p-side contact layer 54. That is, multiple regions each having a high Mg concentration are distributed in a region having a low Mg concentration. In this manner, the p-side contact layer 54 includes a first region R1 provided in a plane (X-Y plane) perpendicular to the Z-axis direction and multiple second regions R2 distributed in the first region R1 along the X-Y plane. The concentration of Mg included in the second region R2 is higher than the concentration of Mg included in the first region R1.

As shown in FIG. 8B, the Mg concentration Cm1 in the first region R1 is approximately 1 atomic percent. The Mg concentration Cm1 in the second region R2 is 2.5 to 3 atomic percent. The Mg concentration Cm1 in the second region R2 is twice or more of the Mg concentration Cm1 in the first region R1.

In this manner, in the semiconductor light emitting device 110 according to the embodiment, it has been found that the multiple second regions R2 each having a high Mg concentration are formed to be distributed in the p-side contact layer 54.

A fluctuation is formed in the Mg concentration in this manner, and thus the polarity reversal is suppressed even in the Mg doping at a high concentration. Then, the formation of the defects is suppressed by the formation of the Mg concentration fluctuation even when the Mg is doped at a high concentration. Accordingly, Mg can be doped at a high concentration. As a result, the contact resistance R would be able to be reduced between the p-side contact layer 54 and the p-side electrode 80 and the drive voltage Vf would be able to be reduced.

The multiple second regions R2 each having a high Mg concentration correspond to the protruding parts 54b, respectively.

That is, the concentration of Mg included in each of the multiple protruding parts 54b is higher than the concentration of Mg included in the flat part 54a. For example, the concentration of Mg included in the multiple protruding parts 54b is more than twice higher than the concentration of Mg included in the flat part 54a. For example, the concentration of Mg included in the multiple protruding parts 54b is approximately 1 atomic percent and the concentration of Mg included in the flat part 54a is approximately 2.5 to 3 atomic percent. In this manner, the concentration of the p-type impurity contained in the multiple protruding parts 54b is higher than the concentration of the p-type impurity contained in the flat part 54a.

In the embodiment, the Mg concentration is increased locally in this protruding part 54b by way of providing the multiple protruding parts 54b in the p-side contact layer 54. That is, the region having a low Mg concentration (first region R1 and flat part 54a) and the regions each having a high Mg concentration (second regions R2 and protruding parts 54b) are formed.

When the density of the protruding parts 54b is too high, the distribution of the regions each having a high Mg concentration is substantially averaged. That is, this corresponds to the case that a part having a high Mg concentration is formed uniformly in the p-side contact layer 54. Therefore, in this state, the crystalline defect is easily generated and the defect is easily enlarged. Therefore, the contact resistance R is increased.

On the other hand, in the embodiment, the polarity reversal can be suppressed and the generation of the defect can be suppressed by way of controlling the concentration in the region (second region R2) having a high Mg concentration. That is, in the embodiment, the density of the regions each having a high Mg concentration (second regions R2) in the X-Y plane is set to 5×10⁷/cm² or more and 2×10⁸/cm² or less. Therefore, the contact resistance R can be reduced and the drive voltage Vf can be reduced.

That is, the localized region having a high Mg concentration suppresses the crystalline quality degradation caused by the doping at a high concentration. Therefore, it becomes possible to perform the doping at a higher concentration than that in the conventional case and to reduce the contact resistance considerably.

It should be noted that, while the case of using Mg for the p-type impurity has been explained above, the embodiment is not limited to this case. Various elements such as Mg, Zn, and C can be used as the p-type impurity. Also in these cases, the degradation of the crystalline quality can be suppressed by way of localizing a region having a high p-type impurity concentration.

That is, the concentration of the p-type impurity included in the second regions R2 is higher than the concentration of the p-type impurity included in the first region R1. Then, the concentration of the p-type impurity included in the multiple protruding parts 54b is higher than the concentration of the p-type impurity included in the flat part 54a.

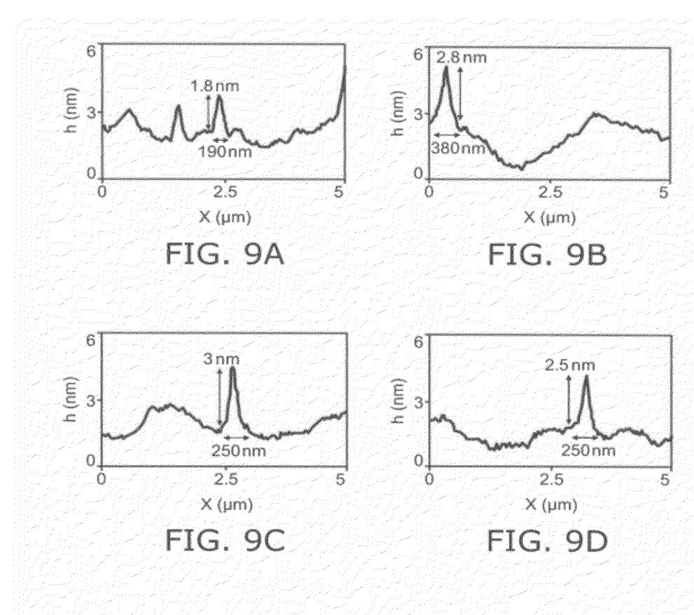

FIGS. 9A to 9D are schematic views illustrating characteristics of the semiconductor light emitting device according to the embodiment.

That is, each of these drawings shows an uneven surface shape of the p-side contact layer 54 after the p-side contact layer 54 has been subjected to various kinds of processing. Each of these drawings is obtained from a result of evaluation for the surface of the p-side contact layer 54 by using the atomic force microscope (AFM). FIG. 9A corresponds to a state just after the p-side contact layer 54 has been formed. FIG. 9B corresponds to a state after processing of ethanol (3 minutes) and water (10 minutes). FIG. 9C corresponds to a state after processing of NH₄F (3 minutes) and water (10 minutes). FIG. 9D corresponds to a state after processing of HCl (+H₂O) (20 minutes) and water (10 minutes).

As shown in FIG. 9A, immediately after the p-side contact layer 54 has been formed, the height (height h1) of the protrusions 54b is 1.8 nm and the radius d2 is 190 nm. At this time, the RMS is 0.54 nm.

As shown in FIG. 9B, after the processing of ethanol and water, the height h1 of the protruding parts 54b is 2.8 nm and the diameter d2 is 380 nm. At this time, the RMS is 0.45 nm.

As shown in FIG. 9C, after the processing of NH₄F and water, the height h1 of the protruding parts 54b is 3 nm and the diameter d2 is 250 nm. At this time, the RMS is 0.45 nm.

As shown in FIG. 9D, after the processing of HCl (+H₂O) and water, the height h1 of the protruding parts 54b is 2.5 nm and the diameter d2 is 250 nm. At this time, the RMS is 0.41 nm.

In this manner, the structure of the protruding parts 54b is not changed substantially even when the p-side contact layer 54 is subjected to the processing using the various chemicals.

It should be noted that, when a polarity reversal layer is formed on the surface of the p-side contact layer 54, the polarity reversal layer is etched by chemicals such as one described above, for example. Therefore, in this case, the uneven surface profile is greatly changed by the processing using the chemicals such as one described above.

In the embodiment, the polarity reversal layer is not formed and the profile of the surface unevenness of the p-side contact layer 54 (protruding parts 54b) on the surface of the p-side contact layer is stable even if the processing using the various chemicals is performed.

As already explained, the density Cp of the protruding parts 54b is changed according to the concentration of the Mg elements introduced into the p-side contact layer 54 in the formation of the p-side contact layer 54. Furthermore, the density Cp of the protruding parts 54b depends on another forming condition. For example, the density Cp of the protruding parts 54b depends on growth speed in the formation of the p-side contact layer 54. According to the experiment, the density Cp tends to be increased when the growth speed is lower. Furthermore, the density Cp of the protruding parts 54b depends on temperature in the formation of the p-side contact layer 54. According to the experiment, the density Cp tends to be increased when the growth temperature is higher. The density Cp of the protruding parts 54b also depends on carrier gas in the formation of the p-side contact layer 54. According to the experiment, the density Cp tends to be increased when nitrogen pressure is higher in growth atmosphere.

In the embodiment, when a transparent electrode such as metal oxide is used as the p-side electrode 80, the effect of the reduction in the contact resistance R and the reduction of the drive voltage Vf becomes larger. That is, when a metal such as Ni and Au is used as the p-side electrode 80, the contact resistance with the p-type semiconductor layer 50 is comparatively low. However, when the metal oxide such as ITO is used as the p-side electrode 80, the contact resistance tends to become higher. Therefore, by combining the configuration of the embodiment with the p-side electrode 80 based on the metal oxide, particularly noticeable effect of reducing the contact resistance and the drive voltage is realized. By using the transparent electrode based on the metal oxide as the p-side electrode 80, it is possible to efficiently extract the light emitted from the light emitting layer 40.

In this manner, in the semiconductor light emitting device 110, the p-side electrode 80 preferably has transparency to the light emitted from the light emitting layer 40. Then, the p-side electrode 80 preferably includes the metal oxide.

Meanwhile, there is a configuration in which unevenness is provided in a semiconductor layer for changing the light path of the emitted light in order to improve the light extraction efficiency. For example, there is known a method of forming protruding parts in the semiconductor layer by selective area growth. The height of the protruding parts in this method is approximately 1.5 μm. Furthermore, there is known a configuration of a semiconductor layer using a polarity reversal layer having unevenness formed by wet etching. In this case, a preferable thickness of the polarity reversal layer is 0.1 μm or more (more preferably, 0.3 μm or more).

In this manner, when the light path of the emitted light is changed by the unevenness, unevenness having a size of approximately the wavelength of the emitted light is used. That is, the unevenness considerably smaller than the wavelength of the emitted light substantially does not change the light path of the emitted light. For example, in the unevenness having a size not larger than one-fourth of the emitted light wavelength, the effect of changing the light path is small.

In the semiconductor light emitting device 110 according to the embodiment, the height (height h1) of the multiple protruding parts 54b along the Z-axis direction is smaller than one-fourth of the dominant wavelength of the light emitted from the light emitting layer 40. The embodiment does not obtain the effect of changing the light path but obtains the effect of reducing the contact resistance R, by using the protruding parts 54b.

Meanwhile, there is a method of forming a periodic structure having a hexagonal pyramid shape by the selective area growth using lithography and etching.

On the other hand, the embodiment forms the protruding parts 54b of the p-side contact layer 54 without using the selective area growth. Therefore, the protruding parts 54b are formed at random at arbitrary positions on the flat part 54a. Then, the embodiment does not use the selective area growth method and thus manufacturing is simple.

Here, a configuration example and a manufacturing condition example will be explained for the semiconductor light emitting device 110 (and 110a) according to the embodiment. It should be noted that the following is an example and various modifications are possible.

Various kinds of material such as sapphire, GaN, SiC, Si, and GaAs can be used as the substrate 10. For the n-type impurity, various elements such as Si, Ge, Te, and Sn can be used.

The thickness of the underlayer 21 is 2 μm, for example. The n-type impurity may be doped into the underlayer 21. The thickness of the n-side contact layer 22 is 4 μm, for example. The doping amount of Si in the n-side contact layer 22 is set to approximately 2×10¹⁸/cm³, for example. Here, each of the respective growth temperatures of the underlayer 21 and the n-side contact layer 22 is set to 1000° C. or more and 1200° C. or less. Furthermore, an In_{0.01}Ga_{0.99}N layer having a thickness of approximately 4 μm may be used as the n-side contact layer 22 instead of the GaN layer. When the In_{0.01}Ga_{0.99}N layer is used, the growth temperature is 700° C. or more and 900° C. or less.

The growth temperature of the first layer and the second layer in the multilayer stacked body 30 is 700° C. or more and 900° C. or less. The n-type impurity may be doped in at least either of the first layer and the second layer.

The growth temperature of the well layer is 600° C. or more and 900° C. or less. The growth temperature of the barrier layer is higher than the growth temperature of the well layer. The growth temperature of the barrier layer is in the range of 600° C. to 1100° C., for example. In this manner, the barrier layer is formed at a temperature higher than the well layer and thus crystalline defects in the light emitting layer 40 can be reduced.

The n-type impurity such as Si or the p-type impurity such as Mg may be doped into the light emitting layer 40. Such impurity may be doped into both of the well layer and the barrier layer or may be doped only in at least some of the well layers and the barrier layers.

Al_{0.2}Ga_{0.8}N into which the p-type impurity are doped is used as the first p-type layer 51. The thickness of the first p-type layer 51 is approximately 10 nm, for example. The Mg concentration in the first p-type layer 51 is set to approximately 1×10¹⁹/cm³, for example. The growth temperature of the first p-type layer 51 is 900° C. or more and 1100° C. or less, for example.

The thickness of the second p-type layer 52 is approximately 100 nm, for example. The Mg concentration in the second p-type layer 52 is set to approximately 1×10¹⁹/cm³, for example. The growth temperature of the second p-type layer 52 is in the range of 900° C. to 1100° C., for example.

The thickness of the third p-type layer 53 is 5 nm, for example. The Mg concentration in the third p-type layer 53 is approximately 1×10²⁰/cm³, for example.

The thickness of the p-side contact layer 54 is 5 nm, for example. The Mg concentration in the p-side contact layer 54 is higher than the Mg concentration in the third p-type layer 53.

A metal organic chemical vapor deposition (MOCVD) method or a molecular beam epitaxy (MBE) method, for example, is used as the crystal growth of the semiconductor layers in the semiconductor light emitting device 110.

In the above description, the semiconductor light emitting device 110 (and 110a) is a light emitting diode (LED). The emission wavelength of the LED can be a wavelength of ultraviolet, violet, blue, blue-green, green, yellow or red. Furthermore, the embodiment can be applied for a laser diode (LD) and the like of ultraviolet, violet, blue, blue-green, green, yellow or red.

The embodiment provides a semiconductor light emitting device having a low drive voltage.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which each of the compositional proportions x, y, and z are changed within the ranges. “Nitride semiconductor” further includes group V elements other than N (nitrogen) in the chemical formula recited above, various elements added to control various properties such as the conductivity type, etc., and various elements included unintentionally.

In the specification of the application, “perpendicular” and “parallel” refer to not only strictly perpendicular and strictly parallel, respectively, but also include, for example, fluctuation due to a manufacturing process, or the like. It is sufficient to be substantially perpendicular and substantially parallel.

Hereinabove, the embodiment of the invention has been described with reference to the specific examples. However, the embodiment of the invention is not limited to these specific examples. For example, one skilled in the art may similarly practice the invention by appropriately selecting a specific configuration of a component included in a semiconductor light emitting device such as an n-type semiconductor layer, a p-type semiconductor layer, a light emitting layer, and an electrode, from known art. Such practice is included in the scope of the invention to the extent that a similar effect thereto is obtained.

Further, any two or more components of the specific examples may be combined with one another within the extent of technical feasibility and this combination is included in the scope of the invention to the extent that the purport of the invention is included.

Moreover, all semiconductor light emitting devices practicable by an appropriate design modification by one skilled in the art based on the semiconductor light emitting device described above as the embodiment of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
an n-type semiconductor layer;
an electrode;
a p-type semiconductor layer provided between the n-type semiconductor layer and the electrode and including a p-side contact layer contacting the electrode; and
a light emitting layer provided between the n-type semiconductor layer and the p-type semiconductor layer,
the p-side contact layer including a flat part having a plane perpendicular to a first direction from the n-type semiconductor layer toward the p-type semiconductor layer and multiple protruding parts protruding from the flat part toward the electrode,
a height of the multiple protruding parts along the first direction being smaller than one-fourth of a dominant wavelength of light emitted from the light emitting layer, and
a density of the multiple protruding parts in the plane being 5×10⁷/cm² or more and 2×10⁸/cm² or less.

2. The device according to claim 1, wherein
a concentration of Mg contained in the multiple protruding parts is higher than a concentration of Mg contained in the flat part.

3. The device according to claim 1, wherein
a concentration of Mg contained in the p-side contact layer is 1×10²⁰/cm³ or more and 5×10²¹/cm³ or less.

4. The device according to claim 1, wherein
the height of the multiple protruding parts along the first direction is 50 nanometers or less.

5. The device according to claim 1, wherein
each of the multiple protruding parts has a base side part on a side of the flat part of the multiple protruding parts, and a tip part on an end side of the multiple protruding parts, and
a diameter of the tip part cut by the plane is smaller than a diameter of the base side part cut by the plane.

6. The device according to claim 1, wherein
the electrode is transparent to the light emitted from the light emitting layer.

7. The device according to claim 1, wherein
the electrode includes a metal oxide.

8. The device according to claim 1, wherein
the p-type semiconductor layer further includes a second p-side contact layer provided between the p-side contact layer and the light emitting layer, and
an average concentration of Mg contained in the p-side contact layer is higher than a concentration of Mg contained in the second contact layer.

9. The device according to claim 1, wherein
a diameter of a portion on a side of the flat part of the multiple protruding parts is 400 nanometers or less.

10. The device according to claim 1, wherein
a concentration of p-type impurity contained in the multiple protruding parts is higher than a concentration of p-type impurity contained in the flat part.

11. The device according to claim 1, wherein
a concentration of Mg contained in the multiple protruding parts is twice or more of a concentration of Mg contained in the flat part.

12. The device according to claim 1, wherein
the protruding parts have a pyramid shape.

13. The device according to claim 1, wherein
the p-side semiconductor layer includes a nitride semiconductor.

14. The device according to claim 1, wherein
the dominant wavelength is 380 nanometers or more and 650 nanometers or less.

15. A semiconductor light emitting device, comprising:
an n-type semiconductor layer;
an electrode;
a p-type semiconductor layer provided between the n-type semiconductor layer and the electrode and including a p-side contact layer contacting the electrode; and
a light emitting layer provided between the n-type semiconductor later and the p-type semiconductor layer,
the p-side contact layer including a first region provided in a plane perpendicular to a first direction from the n-type semiconductor layer toward the p-type semiconductor layer, and multiple second regions distributed within the first region in the plane,
a concentration of p-type impurity contained in the second region being higher than a concentration of p-type impurity contained in the first region, and
a density of the multiple second regions in the plane being 5×10⁷/cm² or more and 2×10⁸/cm² or less.

16. The device according to claim 15, wherein
a concentration of Mg contained in the p-side contact layer is 1×10²⁰/cm³ or more and 5×10²¹/cm³ or less.

17. The device according to claim 15, wherein
the electrode is transparent to the light emitted from the light emitting layer.

18. The device according to claim 15, wherein
the electrode includes a metal oxide.

19. The device according to claim 15, wherein
the p-side semiconductor layer includes a nitride semiconductor.

20. The device according to claim 15, wherein
the dominant wavelength is 380 nanometers or more and 650 nanometers or less.
